(19) United States
(12) Patent Application Publication
(10) Pub. No.: US 2026/0126507 A1
(43) Pub. Date: May 7, 2026

(54) MAGNETIC RESONANCE IMAGING APPARATUS, MAGNETIC RESONANCE IMAGING METHOD, AND COMPUTER-READABLE NON-VOLATILE STORAGE MEDIUM STORING MAGNETIC RESONANCE IMAGING PROGRAM

(71) Applicant: CANON MEDICAL SYSTEMS CORPORATION, Otawara-shi (JP)

(72) Inventor: Hidenori TAKESHIMA, Taito Tokyo (JP)

(73) Assignee: CANON MEDICAL SYSTEMS CORPORATION, Otawara-shi (JP)

(21) Appl. No.: 19/377,115

(22) Filed: Nov. 3, 2025

(30) Foreign Application Priority Data
Nov. 6, 2024 (JP) 2024-194199

(51) Int. Cl. G01R 33/565; G01R 33/561

(52) U.S. Cl. CPC G01R 33/56554; G01R 33/5616

(57) ABSTRACT

A magnetic resonance imaging apparatus according to an embodiment includes processing circuitry. The processing circuitry is configured to, in readout of magnetic resonance data in imaging of a subject, read out the magnetic resonance data for a position along a first direction in k-space and a position along a second direction in the k-space different from the first direction in a batch without applying a refocusing pulse, apply the refocusing pulse and perform phase encoding to reset readout positions of the magnetic resonance data, and read out the magnetic resonance data in a batch such that a total readout time with regard to the readout of the magnetic resonance data does not exceed a predetermined reference time that depends on a spatial resolution.

### CROSS-REFERENCE TO RELATED APPLICATIONS

This application is based upon and claims the benefit of priority from Japanese Patent Application No. 2024-194199, filed on Nov. 6, 2024, the entire contents of which are incorporated herein by reference.

### FIELD

Embodiments described herein relate generally to a magnetic resonance imaging apparatus, a magnetic resonance imaging method, and a computer-readable non-volatile storage medium storing a magnetic resonance imaging program.

### BACKGROUND

There is conventionally a high-speed imaging method called Echo Planar Imaging (hereinafter referred to as EPI) in which all data in k-space is collected without a refocusing pulse. In EPI, since a refocusing pulse is not used, B₀ shifts including chemical shift are accumulated. Therefore, in EPI, chemical shift artifacts appear in the phase encoding direction.

There is also a high-speed imaging method called Fast Spin Echo (hereinafter referred to as FSE). In FSE, a refocusing pulse is applied for each line along the frequency encoding direction in k-space to collect magnetic resonance data. Therefore, in FSE, the B₀ shifts are reset with each collection of one line of magnetic resonance data. However, FSE requires a longer imaging time than EPI due to the application of a refocusing pulse.

Another high-speed imaging method is Gradient and Spin Echo (GRASE). GRASE is an imaging method in which a refocusing pulse is applied every N lines (where N is a natural number equal to or greater than 2) in the phase encoding direction, and magnetic resonance data is collected while interleaving. In this case, the B₀ shifts are reset with each collection of N lines of magnetic resonance data. GRASE is positioned as an intermediate method between EPI and FSE.

EPI is required to quickly capture an image of a subject. However, in EPI, chemical shift appears in the phase encoding direction. Since fat signals appear in different pixels due to the chemical shift, a clear image cannot be obtained in EPI unless fat is suppressed. More specifically, in normal EPI, the sampling interval along the phase encoding direction is longer (slower) than the sampling interval along the frequency encoding direction, so that chemical shift artifacts that depend on the phase encoding direction appear in a magnetic resonance image. As described above, the chemical shift artifacts are reduced in GRASE as compared to EPI because the sampling interval in GRASE is inversely proportional to an interleaving factor (factor that determines the interleaving of readouts in the phase encoding direction).

However, even in GRASE, because the sampling interval in the phase encoding direction is shorter than that in the frequency encoding direction, chemical shift appears in the phase encoding direction. The fundamental reason for the short sampling interval in GRASE is that the total readout time with regard to the frequency encoding direction (a time interval between two temporally adjacent refocusing pulses) is excessively long.

### BRIEF DESCRIPTION OF THE DRAWINGS

FIG. 1 is a block diagram illustrating a configuration of a magnetic resonance imaging (MRI) apparatus according to an embodiment;

FIG. 2 is a diagram illustrating an example of batch readout of magnetic resonance (MR) data according to the embodiment;

FIG. 3 is a diagram illustrating an example of readout by Fast Spin Echo (FSE) and Echo Planar Imaging (EPI) as a comparative example;

FIG. 4 is a diagram illustrating an example of sequence information (sequence) according to the embodiment; and

FIG. 5 is a flowchart illustrating an example of a procedure for a sampling interval reduction imaging process according to the embodiment.

### DETAILED DESCRIPTION

A magnetic resonance imaging apparatus according to an embodiment includes processing circuitry. The processing circuitry is configured to, in readout of magnetic resonance data in imaging of a subject, read out the magnetic resonance data for a position along a first direction in k-space and a position along a second direction in the k-space different from the first direction in a batch without applying a refocusing pulse, apply the refocusing pulse and perform phase encoding to reset readout positions of the magnetic resonance data, and read out the magnetic resonance data in a batch such that a total readout time with regard to the readout of the magnetic resonance data does not exceed a predetermined reference time that depends on a spatial resolution.

Various Embodiments will be described hereinafter with reference to the accompanying drawings.

The contents described in each embodiment can be similarly applied to other embodiments in principle. In the following embodiments, the same reference numerals denote the same parts, and a repetitive description thereof will be omitted as appropriate.

### Embodiment

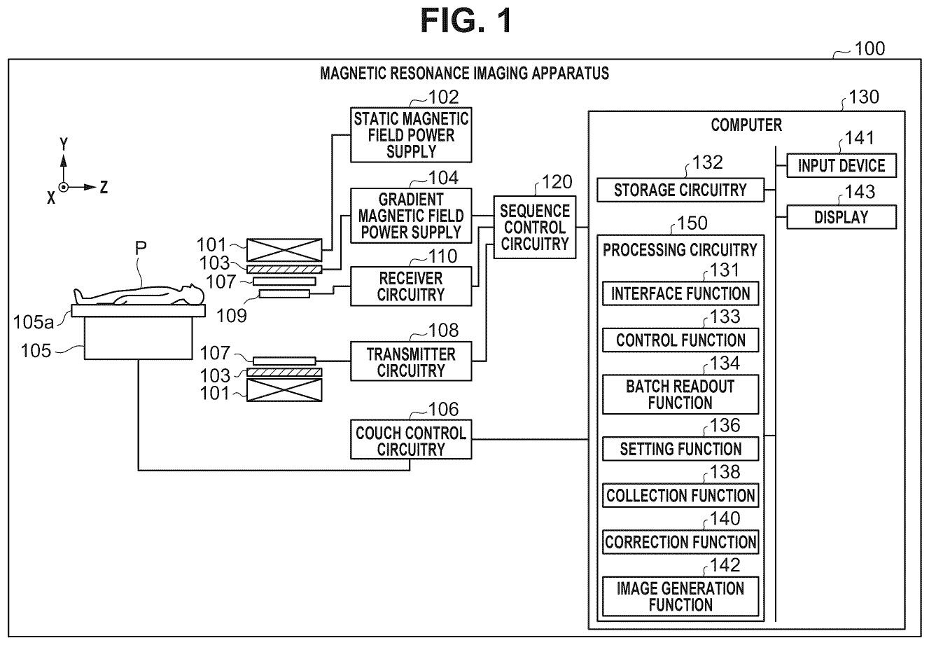

FIG. 1 is a block diagram illustrating a configuration of a magnetic resonance imaging (MRI) apparatus 100 according to an embodiment. As illustrated in FIG. 1, the MRI apparatus 100 includes a static magnetic field magnet 101, a static magnetic field power supply 102, a gradient magnetic field coil 103, a gradient magnetic field power supply 104, a couch 105, couch control circuitry 106, a transmission coil 107, transmitter circuitry 108, a reception coil 109, receiver circuitry 110, sequence control circuitry 120, and a computer 130 (also referred to as an image processing device). The MRI apparatus 100 does not include a subject P (for example, a human body). The configuration illustrated in FIG. 1 is merely an example. For example, the sequence control circuitry 120 and each part in the computer 130 may be integrated or separated as appropriate.

The static magnetic field magnet 101 is a hollow magnet formed in a substantially cylindrical shape, and generates a static magnetic field in an internal space. The static magnetic field magnet 101 is a superconducting magnet or the like, for example, and is excited by receiving a current supplied from the static magnetic field power supply 102. The static magnetic field power supply 102 supplies a current to the static magnetic field magnet 101. The static magnetic field magnet 101 may be a permanent magnet, and in this case, the MRI apparatus 100 does not need to include the static magnetic field power supply 102. Further, the static magnetic field power supply 102 may be provided separately from the MRI apparatus 100.

The gradient magnetic field coil 103 is a hollow coil formed in a substantially cylindrical shape, and is arranged inside the static magnetic field magnet 101. The gradient magnetic field coil 103 is formed by combining three coils corresponding to mutually orthogonal X, Y, and Z axes. These three coils are individually supplied with a current from the gradient magnetic field power supply 104 to generate gradient magnetic fields whose magnetic field strength changes along the X, Y, and Z axes. The gradient magnetic fields of the X, Y, and Z axes generated by the gradient magnetic field coil 103 are a slice gradient magnetic field Gs, a phase encoding gradient magnetic field Ge, and a readout gradient magnetic field Gr, for example. The gradient magnetic field power supply 104 supplies a current to the gradient magnetic field coil 103.

The couch 105 includes a couchtop 105a on which the subject P is to be placed. Under control of the couch control circuitry 106, the couchtop 105a is inserted into a cavity (imaging port) of the gradient magnetic field coil 103 with the subject P placed thereon. The couch 105 is usually installed such that its longitudinal direction is parallel to the central axis of the static magnetic field magnet 101. Under control of the computer 130, the couch control circuitry 106 drives the couch 105 to move the couchtop 105a in the longitudinal direction and the vertical direction.

The transmission coil 107 is arranged inside the gradient magnetic field coil 103, and generates a high-frequency magnetic field upon receiving an radio frequency (RF) pulse from the transmitter circuitry 108. The transmitter circuitry 108 supplies the transmission coil 107 with an RF pulse corresponding to a Larmor frequency determined by the type of atom that is a target and the magnetic field strength.

The reception coil 109 is arranged inside the gradient magnetic field coil 103, and receives a magnetic resonance signal (hereinafter, referred to as an MR signal) emitted from the subject P due to an influence of a high-frequency magnetic field. Upon receipt of the MR signal, the reception coil 109 outputs the received MR signal to the receiver circuitry 110.

The above-described transmission coil 107 and reception coil 109 are merely examples. The transmission coil 107 and the reception coil 109 may be configured by combining one or more coils selected from a coil having only a transmission function, a coil having only a reception function, and a coil having both transmission and reception functions.

The receiver circuitry 110 detects the MR signal output from the reception coil 109 and generates MR data based on the detected MR signal. Specifically, the receiver circuitry 110 generates MR data by digitally converting the MR signal output from the reception coil 109. The receiver circuitry 110 transmits the generated MR data to the sequence control circuitry 120. The receiver circuitry 110 may be provided on a gantry device that includes the static magnetic field magnet 101, the gradient magnetic field coil 103, and the like.

The sequence control circuitry 120 drives the gradient magnetic field power supply 104, the transmitter circuitry 108, and the receiver circuitry 110 based on sequence information transmitted from the computer 130 to capture an image of the subject P. The sequence information is information that defines a procedure for performing imaging, and is also referred to as sequence conditions. The sequence information defines the strength of a current supplied by the gradient magnetic field power supply 104 to the gradient magnetic field coil 103, the timing for supplying the current, the strength of an RF pulse supplied by the transmitter circuitry 108 to the transmission coil 107, the timing for applying the RF pulse, the timing for the receiver circuitry 110 to detect an MR signal, and the like.

For example, the sequence control circuitry 120 is integrated circuitry such as an application specific integrated circuit (ASIC) or a field programmable gate array (FPGA), or electronic circuitry such as a central processing unit (CPU) or a micro processing unit (MPU). The sequence control circuitry 120 corresponds to a sequence control unit.

After driving the gradient magnetic field power supply 104, the transmitter circuitry 108, and the receiver circuitry 110 to capture an image of the subject P, the sequence control circuitry 120 receives MR data from the receiver circuitry 110 and transfers the received MR data to the computer 130.

The computer 130 performs overall control of the MRI apparatus 100, generates images, and the like. The computer 130 includes storage circuitry 132, an input device 141, a display 143, and processing circuitry 150. The processing circuitry 150 includes an interface function 131, a control function 133, a batch readout function 134, a setting function 136, a correction function 140, and an image generation function 142.

The storage circuitry 132 stores the MR data received by the processing circuitry 150 having the interface function 131, various types of data collected by the batch readout function 134 and a collection function 138, various types of image data generated by an image generation function 135, and the like. The storage circuitry 132 also stores the MR data (also called k-space data) arranged in k-space by the control function 133. For example, the storage circuitry 132 is implemented by a semiconductor memory element such as a random access memory (RAM) or a flash memory, a hard disk, an optical disk, or the like. The storage circuitry 132 may be referred to as a memory.

The input device 141 accepts input of various types of instructions and information from a user. The input device 141 is implemented, for example, by a trackball, a switch button, a mouse, a keyboard, a touch pad on which a user can perform an input operation by touching an operation surface, a touch screen in which a display screen and a touch pad are integrated, non-contact input circuitry using an optical sensor, or voice input circuitry. The input device 141 is electrically connected to the processing circuitry 150, and converts an input operation received from a user into an electric signal and outputs the same to the processing circuitry 150. The input device 141 corresponds to an input unit.

In the present specification, the input device 141 is not limited to a device equipped with a physical operation part (input interface) such as a mouse or a keyboard. Examples of the input device 141 include electric signal processing circuitry that receives an electric signal corresponding to an input operation from an external input device provided separately from the MRI apparatus 100, and outputs the electric signal to control circuitry. The input device 141 corresponds to an input unit and may be referred to as an input interface, an operation device, or the like.

Under control of the processing circuitry 150 having the control function 133, the display 143 displays a graphical user interface (GUI) for receiving input of an imaging condition and the like, an image generated by the processing circuitry 150 having the image generation function 142, and the like. The display 143 also displays a result of an analysis by an analysis function 137 described below. The display 143 is implemented, for example, by a display device such as a cathode-ray tube (CRT) display, a liquid crystal display, an organic electroluminescent (EL) display, a light emitting diode (LED) display, a plasma display, or any other display or monitor known in the related art. The display 143 corresponds to a display unit.

Processing functions performed by the interface function 131, the control function 133, the batch readout function 134, the setting function 136, the correction function 140, and the image generation function 142 are stored in the storage circuitry 132 in the form of programs executable by the computer 130. The processing circuitry 150 is a processor that implements functions corresponding to the programs by reading and executing the programs from the storage circuitry 132. In other words, the processing circuitry 150 having read the programs has the functions illustrated in the processing circuitry 150 in FIG. 1.

While, in FIG. 1, the processing functions performed by the interface function 131, the control function 133, the batch readout function 134, the setting function 136, the correction function 140, and the image generation function 142 are implemented by a single piece of processing circuitry 150, the processing circuitry 150 may be configured by combining a plurality of independent processors, and each of the processors may execute a program to implement the function. In other words, each of the above-described functions may be configured as a program, and the single piece of processing circuitry 150 may execute each program, or a specific function may be implemented by dedicated independent program execution circuitry.

The term “processor” used in the above description refers to, for example, circuitry such as a CPU, a graphical processing unit (GPU), an application specific integrated circuit, or a programmable logic device (for example, a simple programmable logic device (SPLD), a complex programmable logic device (CPLD), or a field programmable gate array (FPGA)). The processor implements the functions by reading and executing the programs stored in the storage circuitry 132.

Instead of storing the programs in the storage circuitry 132, the programs may be directly built in the circuitry of the processor. In this case, the processor implements the functions by reading and executing the programs built in the circuitry. The couch control circuitry 106, the transmitter circuitry 108, the receiver circuitry 110, and the like are also similarly composed of electronic circuitry such as the above-described processors.

The processing circuitry 150 uses the interface function 131 to transmit sequence information to the sequence control circuitry 120 and receive MR data from the sequence control circuitry 120. Upon receipt of the MR data, the processing circuitry 150 having the interface function 131 stores the received MR data in the storage circuitry 132. The processing circuitry 150 that implements the interface function 131 corresponds to an interface unit.

The processing circuitry 150 uses the control function 133 to perform overall control of the MRI apparatus 100, and control image capturing, image generation, image display, and the like. For example, the processing circuitry 150 having the control function 133 accepts input of an imaging condition (imaging parameter or the like) on the GUI, and generates sequence information according to the accepted imaging condition. The processing circuitry 150 having the control function 133 also transmits the generated sequence information to the sequence control circuitry 120. The sequence information related to the present embodiment will be described below.

Hereinafter, three axial directions in k-space are referred to as kx, ky, and kz. In reading magnetic resonance data in imaging of the subject P, the processing circuitry 150 uses the batch readout function 134 to read the magnetic resonance data for positions along a first direction in the k-space and positions along a second direction in the k-space different from the first direction in a batch without applying a refocusing pulse. The first direction is, for example, a kx direction in the k-space. In this case, the second direction is a ky direction in the k-space. The first direction may be the ky direction in the k-space, for example. In this case, the second direction is the kx direction in the k-space.

Hereinafter, for the sake of specific description, the first direction is set as the kx direction and the second direction is set as the ky direction. In this case, after application of a refocusing pulse, the batch readout function 134 reads MR data for positions along the kx direction and positions along the ky direction in a batch without a refocusing pulse.

More specifically, the batch readout function 134 executes GRASE under a condition that the total readout time between two adjacent refocusing pulses is short, for example. Specifically, the batch readout function 134 slightly modulates the readout in GRASE in the ky direction.

In batch readout in the present embodiment, readout positions are modulated in the ky direction in a plane having 256 readout positions in the kx direction (kx=256) and three readout positions in the ky direction (ky=3). The readout positions may be modulated horizontally and vertically or obliquely with respect to the kx direction.

For example, in the batch readout in the present embodiment, each of a plurality of readout lines in k-space is modulated in the ky direction, and thus has a predetermined width in the ky direction. More specifically, each of the plurality of readout lines in the present embodiment corresponds to several readout lines in FSE. Therefore, the batch readout function 134 reads out MR data in a batch over a predetermined width corresponding to several readout lines in FSE.

Accordingly, each of the plurality of readout lines in the present embodiment corresponds to several readout lines in FSE depending on the width of the modulation in the ky direction. Also, each of the plurality of readout lines in the present embodiment is treated in the same way as several readout lines in FSE.

In the present embodiment, each of the plurality of readout lines is, for example, subjected to k-space ordering similar to that in FSE. For example, in the case of T1-weighted (T1W) imaging, centric view ordering (a method in which phase encoding is performed a row including a low-frequency component at the center of k-space to a row including a high-frequency component) may be applied. In the case of T2-weighted (T2W) imaging, data is acquired such that the desired time of echo (TE) is located at the center of the k-space.

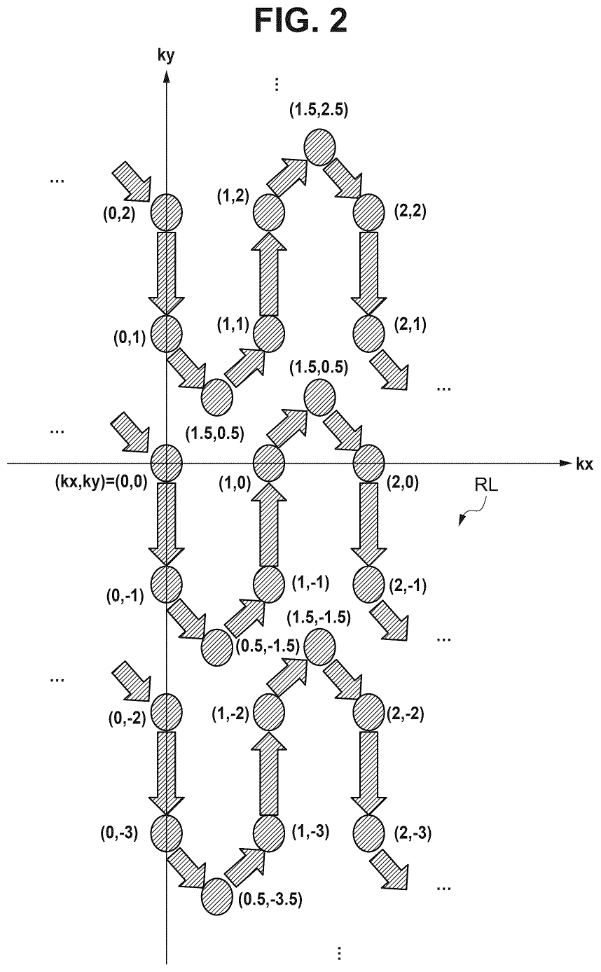

FIG. 2 is a diagram illustrating an example of batch readout of MR data. As illustrated in FIG. 2, the readout positions of MR data along the ky direction of one readout line RL are four points (for example, ky=0.5, 0, 1, 1.5 in a region including the center of k-space). The readout positions of MR data in the ky direction are not limited to four points, and may be two to five points. As illustrated in FIG. 2, the readout positions of MR data in the ky direction do not have to be at equal intervals (constant gradient).

A line for reading out MR data (hereinafter, referred to as a readout line) is modulated such that a sampling interval of MR data in the kx direction and a sampling interval of MR data in the ky direction are substantially equal, for example, as illustrated in FIG. 2. Accordingly, the shape of one readout line (frequency encoding direction) is rounded zigzag (S-shaped or inverted S-shaped) such that the sampling intervals in the kx direction and the ky direction are substantially equal.

As illustrated in FIG. 2, oblique directions with respect to the kx direction in one readout line RL are not limited to two points (ky=−1.5, 0.5), and may be one point or three points. While the shape of the readout line RL illustrated in FIG. 2 is angular, the actual readout positions of the MR data are set on a curved line bent in an S shape along the kx direction, for example. The shape of the readout line of the MR data formed by the first direction and the second direction is not limited to an S shape in k-space, and may be an inverted S shape. The readout line of the MR data along the S shape or the inverted S shape in the k-space corresponds to frequency encoding. In FIG. 2, in addition to the integer lattice points in the k-space, half-integer lattice points are set as the readout positions of the MR data. This enables to shorten the imaging time. The half-integer lattice points are not essential as the readout positions of the MR data, and may not be provided.

The batch readout function 134 reads out the MR data in a batch such that the total readout time with regard to readout of the MR data does not exceed a predetermined reference time that depends on spatial resolution. The reference time is preset as a time during which chemical shift does not appear in an MR image. In FSE as a comparative example, a phase error due to chemical shift is reset every time by a refocusing pulse. In GRASE and EPI as comparative examples, phase errors are accumulated over the duration of the readout time.

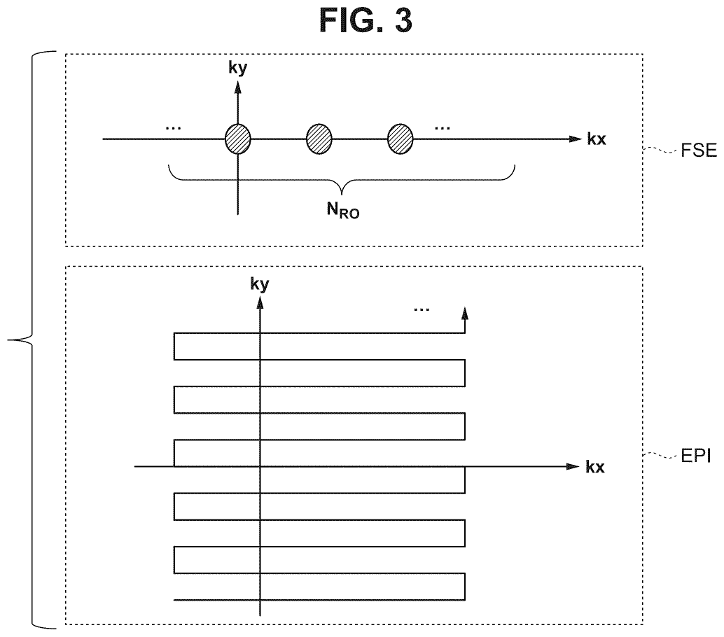

FIG. 3 illustrates an example of readout by FSE and EPI as a comparative example. In FSE, phase errors (cumulative phase error) accumulated in one line related to readout in k-space is the product of the chemical shift, the dwell rate, and the collection points of MR data on one readout line. The dwell rate, also referred to as dwell time or dwell unit, corresponds to the collection time of MR data per sample in readout.

In FSE, chemical shift along the frequency encoding direction is very small so that it can be regarded as zero. In EPI and GRASE, the cumulative phase error in frequency encoding is obtained by multiplying total imaging time by chemical shift. In EPI and GRASE, the amount of chemical shift in the frequency encoding direction is a value obtained by dividing the product of chemical shift and total imaging time by the number of samples of readout (hereinafter, referred to as readout samples) in the frequency encoding direction.

For example, if a quotient value obtained by dividing the total imaging time by the number of readout samples in the frequency encoding direction exceeds 1, chemical shift artifacts appear in the MR image. The greater the quotient value is above 1, the more noticeable the chemical shift artifacts become in the MR image. For this reason, in the present embodiment, the total imaging time is controlled such that the quotient value is less than a design threshold. The design threshold (also referred to as a predetermined reference time) is 1, for example, but is not limited to 1 and may be 2 or 3.

The design threshold is preset and stored in the storage circuitry 132. The total imaging time is controlled, for example, by the number of readout positions along the readout line RL illustrated in FIG. 2. This allows the batch readout function 134 to read out the MR data in a batch such that the total readout time with regard to readout of the MR data does not exceed the predetermined reference time that depends on the spatial resolution. The processing circuitry 150 that implements the batch readout function 134 corresponds to a batch readout unit. The batch readout function 134 may be provided in the sequence control circuitry 120.

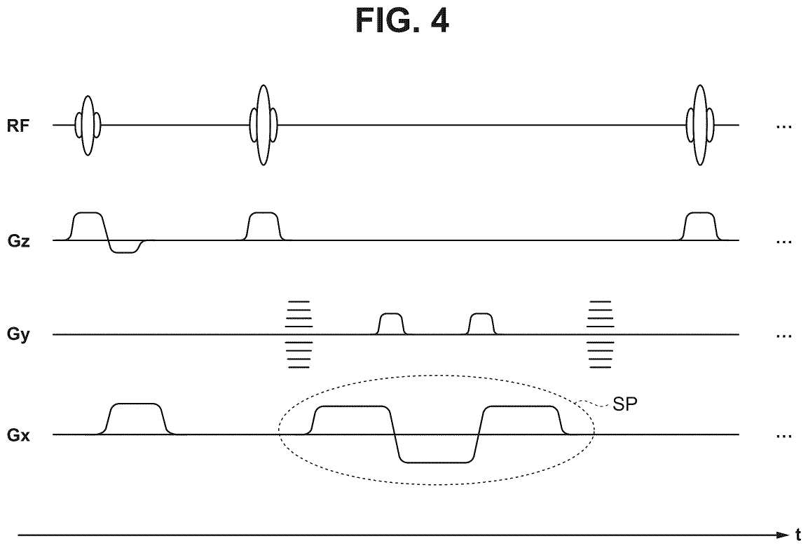

FIG. 4 is a diagram illustrating an example of sequence information (sequence) according to the present embodiment. In the sequence illustrated in FIG. 4, an interleaving factor of three is employed as an example. In a trapezoid SP indicating the application of a readout gradient magnetic field in Gx (a coil which generates gradient magnetic field in x-axis) illustrated in FIG. 4, a series of pulses in which the width of the upper base of the trapezoid is shorter than that in GRASE is employed in the present embodiment.

The processing circuitry 150 uses the setting function 136 to apply a refocusing pulse and execute phase encoding, thereby resetting the readout positions of the MR data. After the batch readout of the MR data by the batch readout function 134, the setting function 136 applies a refocusing pulse to the subject P and executes phase encoding. Accordingly, after the batch readout of the MR data, the setting function 136 resets the readout positions of the MR data on the readout line. The processing circuitry 150 that implements the setting function 136 corresponds to a setting unit. The setting function 136 may be provided in the sequence control circuitry 120.

The processing circuitry 150 uses the collection function 138 to collect first correction data for positions along the first direction in a region including the center of k-space in a batch without applying a refocusing pulse. The readout line of the first correction data is along the kx direction, for example. In this case, the collection function 138 collects the first correction data for a region including the center of the k-space (for example, the k-space center). The readout line of the first correction data along the kx direction corresponds to the frequency encoding.

The collection function 138 stores the first correction data in the storage circuitry 132. The first correction data is collected before or after a main scan. The first correction data corresponds to MR data repeatedly collected from the readout line along kx=0 a predetermined number of times, for example.

The collection function 138 may also collect second correction data by performing first encoding with regard to the first direction and then second encoding with regard to the second direction. In this case, the readout line of the second correction data corresponds to the S-shaped readout line illustrated in FIG. 2. The entire S-shaped readout line corresponds to the frequency encoding and corresponds to one readout.

The collection function 138 may collect the second correction data for positions along the first direction and positions along the second direction in a region including the center of k-space in a batch without applying a refocusing pulse. In this case, the readout line of the second correction data formed by the positions along the first direction and the positions along the second direction has an S-shape and an inverted S-shape in the region including the center of the k-space. Specifically, the readout line of the second correction data corresponds to an S-shaped or an inverted S-shaped readout line in the region including the center of the k-space illustrated in FIG. 2. The entire S-shaped and inverted S-shaped readout line corresponds to the frequency encoding and corresponds to one readout. The collection function 138 stores the second correction data in the storage circuitry 132. The second correction data is collected before or after the main scan.

The collection function 138 may collect at least one of the first correction data and the second correction data a plurality of times in a region including the center of k-space. In this case, the setting function 136 applies a refocusing pulse and executes phase encoding in each of the plurality of times of collection of at least one of the first correction data and the second correction data, thereby resetting the readout positions of at least one of the first correction data and the second correction data.

The collection function 138 may also collect at least one of the first correction data and the second correction data at a higher density than the density of collection of the MR data read in k-space by the batch readout function 134. A known method can be applied to the collection at a higher density, and therefore description thereof will be omitted.

The collection function 138 collects at least one of the first correction data and the second correction data. The processing circuitry 150 that implements the collection function 138 corresponds to a collection unit. The collection function 138 may be provided in the sequence control circuitry 120 or may be implemented by the batch readout function 134.

The processing circuitry 150 uses the correction function 140 to correct the positions of the MR data in k-space using either the first correction data or the second correction data. The correction function 140 may also correct the positions of the MR data in the k-space using the first correction data and the second correction data. The correction of the positions of the MR data by the correction function 140 corresponds to gridding, for example. A gridding process can be performed by a known method (for example, J. I. Jackson, C. H. Meyer, D. G. Nishimura, A. Macovski, “Selection of a convolution function for Fourier inversion using gridding (computerised tomography application)”, in IEEE Transactions on Medical Imaging, vol. 10, no. 3, pp. 473 to 478, September 1991), and thus description thereof will be omitted.

The correction may be performed by the image generation function 142 at the time of reconstruction of an MR image. In this case, the process implemented by the correction function 140 is executed by the image generation function 142. The processing circuitry 150 that implements the correction function 140 corresponds to a correction unit.

The processing circuitry 150 uses the image generation function 142 to read out the corrected MR data (k-space data) from the storage circuitry 132 and perform a reconstruction process such as Fourier transform on the read k-space data to generate an MR image. A known method can be applied to generate the MR image, so description thereof will be omitted. The processing circuitry 150 that implements the image generation function 142 corresponds to an image generation unit.

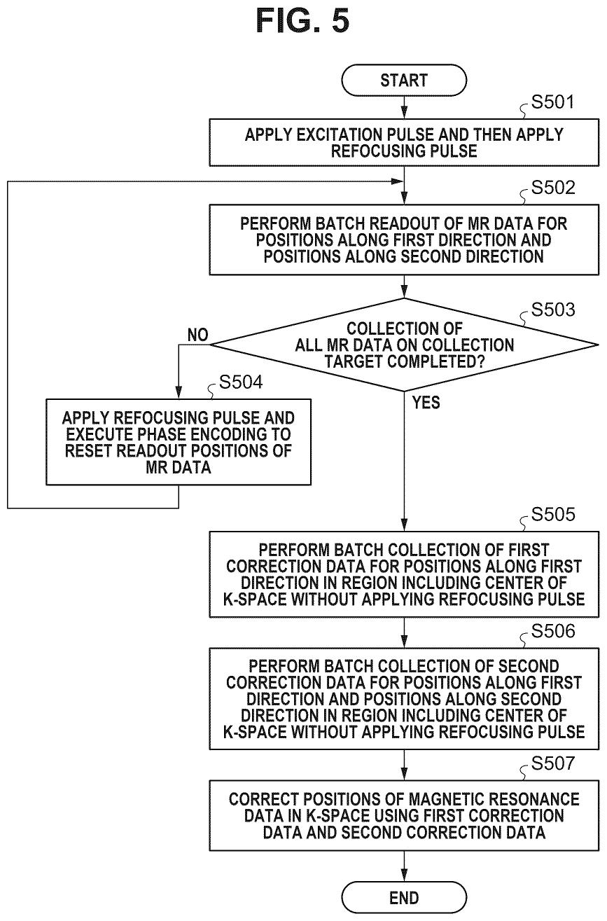

An overall configuration of the MRI apparatus 100 according to the embodiment has been described above. With the above-described configuration, the MRI apparatus 100 according to the embodiment executes a process of imaging the subject P by reducing the sampling interval in the phase encoding direction to a level comparable to the sampling interval in the frequency encoding direction (hereinafter referred to as a sampling interval reduction imaging process). Hereinafter, a procedure related to the sampling interval reduction imaging process will be described with reference to FIG. 5. FIG. 5 is a flowchart illustrating an example of the procedure for the sampling interval reduction imaging process.

### Sampling Interval Reduction Imaging Process

### Step S501

The sequence control circuitry 120 applies an excitation pulse (RF pulse) to the subject P. At this time, the sequence control circuitry 120 applies a gradient magnetic field (Gz) related to slice selection to the subject P together with the excitation pulse. Subsequently, after a lapse of a predetermined time, the sequence control circuitry 120 applies a refocusing pulse (RF pulse) to the subject P. At this time, the sequence control circuitry 120 applies a gradient magnetic field (Gz) related to slice selection to the subject P together with the refocusing pulse.

### Step S502

For MR data collection, the sequence control circuitry 120 applies a gradient magnetic field to the subject P so as to implement one readout line as illustrated in FIG. 2. A timing for applying the gradient magnetic field with regard to the readout of MR data is set in advance such that the total readout time with regard to the readout of the MR data does not exceed a predetermined reference time that depends on the spatial resolution. The receiver circuitry 110 receives the MR data via the reception coil 109 and outputs the MR data to the sequence control circuitry 120.

Accordingly, the processing circuitry 150 uses the batch readout function 134 to read out MR data for positions along the first direction and positions along the second direction in a batch without applying a refocusing pulse. For example, the batch readout function 134 reads out MR data in a batch along a readout line (in an S-shape or inverted S-shape in k-space) of the MR data formed by the positions along the first direction and the positions along the second direction without applying a refocusing pulse. The batch readout function 134 stores the MR data read out in a batch in the storage circuitry 132. Processing in this step corresponds to, for example, collection in one line in FSE as a comparative example or collection in a plurality of readout lines between two adjacent refocusing pulses in GRASE as a comparative example.

### Step S503

The processing circuitry 150 determines whether all MR data related to a collection target, i.e., all MR data arranged in k-space with regard to image reconstruction, have been collected. If the collection of all MR data related to the collection target has not been completed (NO in step S503), the processing proceeds to step S504. Accordingly, readout of MR data and resetting of the readout positions are repeatedly performed over a predetermined range in k-space. The predetermined range corresponds to a preset imaging range. If the collection of all the MR data related to the collection target has been completed (YES in step S503), the processing proceeds to step S505.

### Step S504

The processing circuitry 150 uses the setting function 136 to apply a refocusing pulse and execute phase encoding, thereby resetting the readout positions of the MR data. The reset readout positions of the MR data correspond to readout positions of a readout line (S-shaped in k-space) different from the readout line RL (for example, S-shaped in the k-space illustrated in FIG. 2) read out in step S502. For example, the setting function 136 applies a refocusing pulse (180° pulse) to the subject P via the sequence control circuitry 120. Subsequently, the setting function 136 applies a gradient magnetic field related to phase encoding to the subject P via the sequence control circuitry 120 to set the readout positions. Then, the processing in step S502 and the subsequent steps is repeated.

### Step S505

The processing circuitry 150 uses the collection function 138 to collect the first correction data for positions along the first direction in a region including the center of k-space in a batch without applying a refocusing pulse. For example, the collection function 138 collects the first correction data by repeatedly performing frequency encoding on a readout line along kx=0 a predetermined number of times.

The collection function 138 stores the collected first correction data in the storage circuitry 132. The first correction data may be collected before the processing related to the main scan (steps S501 to S504). In the case of correcting MR data using only the second correction data described below, this step is unnecessary.

### Step S506

The processing circuitry 150 uses the collection function 138 to collect the second correction data for positions along the first direction and positions along the second direction in a region including the center of k-space in a batch without applying a refocusing pulse. The readout line of the second correction data formed by the positions along the first direction and the positions along the second direction has an S-shape and an inverted S-shape in the region including the center of the k-space.

For example, the collection function 138 collects the second correction data by performing batch frequency encoding on the S-shaped and inverted S-shaped readout line in a region including the center (kx=0, ky=0) of k-space. The collection function 138 stores the collected second correction data in the storage circuitry 132. The second correction data may be collected before the processing related to the main scan (steps S501 to S504). In the case of correcting MR data using only the first correction data, this step is unnecessary. The second correction data may be collected before collection of the first correction data.

The collection function 138 may collect at least one of the first correction data and the second correction data a plurality of times in a region including the center of k-space. In this case, the setting function 136 applies a refocusing pulse and executes phase encoding in each of the plurality of times of collection of at least one of the first correction data and the second correction data. Accordingly, the setting function 136 resets the readout positions of at least one of the first correction data and the second correction data. The collection function 138 may also collect at least one of the first correction data and the second correction data at a higher density than the density of collection of magnetic resonance data in the k-space.

### Step S507

The processing circuitry 150 uses the correction function 140 to correct the positions of the MR data in k-space using the first correction data and the second correction data. The correction function 140 may correct the positions of the MR data in the k-space using the first correction data or the second correction data. In this case, since it is not necessary to collect the correction data that is not to be used for the correction, the step of collecting the correction data that is not to be used for the correction is not necessary in the sampling interval reduction imaging process.

The processing circuitry 150 reads out the corrected MR data (k-space data) from the storage circuitry 132 and performs a reconstruction process such as Fourier transform on the read k-space data to generate an MR image. In a case where the image generation function 142 executes the correction, the image generation function 142 corrects the positions of the MR data in k-space using at least one of the first correction data and the second correction data (i.e., using the first correction data and/or the second correction data), and generates an MR image based on the corrected MR data (k-space data).

In reading out MR data in imaging of the subject P, the MRI apparatus 100 according to the embodiment described above reads out the MR data in a batch for positions along the first direction in k-space and positions along the second direction different from the first direction in the k-space without applying a refocusing pulse, applies the refocusing pulse and performs phase encoding to reset the readout positions of the MR data, and reads out the MR data in a batch such that the total readout time with regard to the reading out of the MR data does not exceed a predetermined reference time that depends on the spatial resolution. For example, in the MRI apparatus 100 according to the embodiment, the readout line of the magnetic resonance data formed by the positions along the first direction and the positions along the second direction has an S-shape or an inverted S-shape in the k-space.

Accordingly, with the MRI apparatus 100 according to the embodiment, it is possible to set an S-shaped readout line such that a value obtained by dividing the product of the chemical shift and the total imaging time by the number of readout samples in the frequency encoding direction is smaller than the reference time, and perform imaging with a sampling interval in the phase encoding direction approximately equal to a sampling interval in the frequency encoding direction.

The MRI apparatus 100 according to the embodiment collects the first correction data for positions along the first direction in a region including the center of k-space in a batch without applying a refocusing pulse, and corrects the positions of the MR data in the k-space using the first correction data. The MRI apparatus 100 according to the embodiment also collects the second correction data for positions along the first direction and positions along the second direction in a region including the center of the k-space in a batch without applying a refocusing pulse. The readout line of the second correction data formed by the positions along the first direction and the positions along the second direction has an S-shape and an inverted S-shape in the region including the center of the k-space. The MRI apparatus 100 according to the embodiment corrects the positions of the MR data in the k-space using at least one of the first correction data and the second correction data.

The MRI apparatus 100 according to the embodiment collects at least one of the first correction data and the second correction data a plurality of times in a region including the center of k-space, and applies a refocusing pulse and executes phase encoding in each of the plurality of times of collection of at least one of the first correction data and the second correction data, thereby to reset the readout positions of at least one of the first correction data and the second correction data. The MRI apparatus 100 according to the embodiment also collects at least one of the first correction data and the second correction data at a higher density than the density of collection of MR data in the k-space.

Consequently, the MRI apparatus 100 according to the embodiment is able to correct the MR data by collecting various types of correction data in accordance with the readout lines of the MR data illustrated in FIG. 2.

As described above, the MRI apparatus 100 according to the embodiment can quickly capture an image of the subject P as in EPI or GRASE without an influence of chemical shift as in FSE. Further, the MRI apparatus 100 according to the embodiment can generate an MR image in which the influence of chemical shift is reduced by correcting MR data using correction data collected in accordance with the readout lines. Based on the above, the MRI apparatus 100 according to the embodiment can reduce the burden on the subject P by shortening the examination time, and improve throughput of an examination by generating an MR image in which chemical shift artifacts are reduced.

In the case of implementing the technical idea of the embodiment by an MRI method, the MRI method includes, in reading out MR data in imaging of a subject P, reading out the MR data for positions along a first direction in k-space and positions along a second direction different from the first direction in the k-space in a batch without applying a refocusing pulse, applying the refocusing pulse and executing phase encoding to reset the readout positions of the MR data, and repeatedly performing the readout of the MR data and the resetting of the readout positions over a predetermined range in the k-space, and reading out the MR data in a batch includes reading out the MR data in a batch such that the total readout time with regard to the readout of the MR data does not exceed a predetermined reference time that depends on a spatial resolution. The procedure and effect of the sampling interval reduction imaging process executed by the MRI method are similar to those of the embodiment, and thus description thereof will be omitted.

In the case of implementing the technical ideas of the embodiment by an MRI program, the MRI program causes a computer to, in readout of MR data in imaging of a subject P, read out the MR data for positions along a first direction in k-space and positions along a second direction different from the first direction in the k-space in a batch without applying a refocusing pulse, apply the refocusing pulse and execute phase encoding to reset the readout positions of the MR data, and repeatedly perform the readout of the MR data and the resetting of the readout positions over a predetermined range in the k-space. The reading out of the MR data in a batch refers to reading out the MR data in a batch such that the total readout time with regard to the readout of the MR data does not exceed a predetermined reference time that depends on a spatial resolution.

For example, the sampling interval reduction imaging process can be implemented by installing a collection program in a computer in an MRI apparatus or the like and loading the program in a memory. In this case, an MRI program capable of causing a computer to execute the sampling interval reduction imaging process can be stored in a storage medium such as a magnetic disk (such as a hard disk), an optical disc (such as a compact disc read only memory (CD-ROM), a digital versatile disc (DVD), or the like), or a semiconductor memory and be distributed. The distribution of the MRI program is not limited to distribution via the above-described media, and may be carried out using a telecommunication function, such as downloading via the Internet, for example. The procedure and effects of the sampling interval reduction imaging process executed by the MRI program are the same as those in the embodiment, and thus description thereof will be omitted.

According to the embodiment described above, it is possible to collect MR data at high speed while reducing the influence of chemical shift.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus comprising processing circuitry configured to:
in readout of magnetic resonance data in imaging of a subject, read out the magnetic resonance data for a position along a first direction in k-space and a position along a second direction in the k-space different from the first direction in a batch without applying a refocusing pulse;
apply the refocusing pulse and perform phase encoding to reset readout positions of the magnetic resonance data; and
read out the magnetic resonance data in a batch such that a total readout time with regard to the readout of the magnetic resonance data does not exceed a predetermined reference time that depends on a spatial resolution.

2. The magnetic resonance imaging apparatus according to claim 1, wherein a readout line of the magnetic resonance data formed by the position along the first direction and the position along the second direction has an S-shape or an inverted S-shape in the k-space.

3. The magnetic resonance imaging apparatus according to claim 1,
wherein the processing circuitry collects first correction data for the position along the first direction in a region including a center of the k-space in a batch without applying a refocusing pulse, and
wherein the processing circuitry corrects a position of the magnetic resonance data in the k-space using the first correction data.

4. The magnetic resonance imaging apparatus according to claim 3,
wherein the processing circuitry collects second correction data for the position along the first direction and the position along the second direction in the region including the center of the k-space in a batch without applying a refocusing pulse,
wherein a readout line of the second correction data formed by the position along the first direction and the position along the second direction has an S-shape and an inverted S-shape in the region including the center of the k-space, and
wherein the processing circuitry corrects the position of the magnetic resonance data in the k-space using at least one of the first correction data and the second correction data.

5. The magnetic resonance imaging apparatus according to claim 4,
wherein the processing circuitry collects at least one of the first correction data and the second correction data a plurality of times in the region including the center of the k-space, and
wherein the processing circuitry applies the refocusing pulse and executes phase encoding in each of the plurality of times of collection of at least one of the first correction data and the second correction data, thereby to reset readout positions of at least one of the first correction data and the second correction data.

6. The magnetic resonance imaging apparatus according to claim 4, wherein the processing circuitry collects at least one of the first correction data and the second correction data at a higher density than a density of collection of the magnetic resonance data in the k-space.

7. A magnetic resonance imaging method, comprising:
in readout of magnetic resonance data in imaging of a subject, reading out the magnetic resonance data for a position along a first direction in k-space and a position along a second direction in the k-space different from the first direction in a batch without applying a refocusing pulse;
applying the refocusing pulse and performing phase encoding to reset readout positions of the magnetic resonance data; and
repeatedly performing reading out of the magnetic resonance data and resetting of the readout positions over a predetermined range in the k-space,
wherein reading out the magnetic resonance data in a batch refers to reading out the magnetic resonance data in a batch such that a total readout time with regard to the readout of the magnetic resonance data does not exceed a predetermined reference time that depends on a spatial resolution.

8. A computer-readable non-volatile storage medium storing a magnetic resonance imaging program for causing a computer to:
in readout of magnetic resonance data in imaging of a subject, read out the magnetic resonance data for a position along a first direction in k-space and a position along a second direction in the k-space different from the first direction in a batch without applying a refocusing pulse;
apply the refocusing pulse and perform phase encoding to reset readout positions of the magnetic resonance data; and
repeatedly perform reading out of the magnetic resonance data and resetting of the readout positions over a predetermined range in the k-space,
wherein reading out the magnetic resonance data in a batch refers to reading out the magnetic resonance data in a batch such that a total readout time with regard to the readout of the magnetic resonance data does not exceed a predetermined reference time that depends on a spatial resolution.
